(19) United States
(12) Patent Application Publication
(10) Pub. No.: US 2013/0134569 A1
(43) Pub. Date: May 30, 2013

(54) SEMICONDUCTOR PACKAGE

(71) Applicant: Job Ha, Gyunggi-do (KR)

(72) Inventor: Job Ha, Gyunggi-do (KR)

(73) Assignee: SAMSUNG ELECTRO-MECHANICS CO., LTD., Gyunggi-do (KR)

(21) Appl. No.: 13/402,117

(22) Filed: Feb. 22, 2012

(30) Foreign Application Priority Data
Nov. 30, 2011 (KR) 1020110126760

(51) Int. Cl. H01L 23/495

(52) U.S. Cl. 257/676; 257/E23.031

(57) ABSTRACT

Disclosed herein is a semiconductor package.

The semiconductor package includes: a substrate having a semiconductor device mounted on a top portion thereof; a housing surrounding the semiconductor device and the substrate so as to isolate them from the outside; at least one lead frame disposed on the top portion of the substrate while being spaced apart from one another; and a clip electrically connecting the substrate with at least one lead frame.

### CROSS REFERENCE TO RELATED APPLICATION

This application claims the benefit of Korean Patent Application No. 10-2011-0126760, filed on Nov. 30, 2011, entitled “Semiconductor Package,” which is hereby incorporated by reference in its entirety into this application.

### BACKGROUND OF THE INVENTION

1. Technical Field

The present invention relates to a semiconductor package.

2. Description of the Related Art

As electronic devices are slim and small, a demand for high-density and high-integrated package that is a core component thereof has been increased. Therefore, a semiconductor package having various structures has been manufactured by using various types of substrates such as a lead frame, a printed circuit board, a circuit film, or the like. In the semiconductor package according to the prior art, a semiconductor device and a conductive track are connected with each other by a wire. In addition, the semiconductor package has a structure in which the conductive track and a lead frame are connected with each other by the wire (Korean Laid-Open Patent Publication, No. 10-2010-0120006). However, inter-metallic bonding such as wiring bonding or soldering for bonding the conductive track and the lead frame is vulnerable to factors such as thermal stress, or the like, due to a difference in thermal expansion rate between materials. That is, the bonding method between components configuring the semiconductor package according to the prior art affects the security of the long-term reliability of the semiconductor package.

### SUMMARY OF THE INVENTION

The present invention has been made in an effort to provide a semiconductor package capable of stably transferring electrical signals.

Further, the present invention has been made in an effort to provide a semiconductor package capable of securing long-term reliability from thermal and physical impact.

In addition, the present invention has been made in an effort to provide a semiconductor package capable of improving productivity and yield by implementing electrical connection with a simple assembling process.

According to a preferred embodiment of the present invention, there is provided a semiconductor package, including: a substrate having a semiconductor device mounted on a top portion thereof; a housing surrounding the semiconductor device and the substrate so as to isolate them from the outside; at least one lead frame disposed on the top portion of the substrate while being spaced apart from one another; and a clip electrically connecting the substrate with at least one lead frames.

The clip may be made of conductive metals.

The clip may be an elastic member.

A top portion of the clip may be fastened with the lead frame by being inserted in a form surrounding both sides of an end of the lead frame.

The top portion of the clip may be fastened with the lead frame by being inserted in a form surrounding both sides and the top portion of the end of the lead frame.

The bottom portion of the clip may have at least one end contacting the substrate.

The inside of the housing may be filled with an insulating resin.

According to another preferred embodiment of the present invention, there is provided a semiconductor package, including: a first substrate having a first semiconductor device mounted on a top portion thereof; a second substrate formed so as to be spaced apart from the first substrate and having a second semiconductor device mounted thereon; a housing surrounding the first semiconductor device and the first substrate so as to isolate them from the outside; at least one lead frame disposed on a top portion of the substrate while being spaced apart from one another; a first clip electrically connecting the first substrate with at least one lead frame; and a second clip electrically connecting the first substrate with the second substrate.

The semiconductor package may further include a third clip electrically connecting the second substrate with the at least one lead frame.

The first clip to the third clip may be made of conductive metals.

The first clip to the third clip may be an elastic member.

The top portions of at least one of the first clip to the third clip may be fastened with each other by being inserted in a form surrounding both sides of the end of the at least one lead frame.

The top portions of at least one of the first clip to the third clip may be fastened with each other by being inserted in a form surrounding both sides and the top portion of the end of the at least one lead frame.

The bottom portions of at least one of the first clip to the third clip may have at least one contact end contacting the first substrate or the second substrate.

The top portion of the second clip may have a contact end contacting the first substrate or the second substrate.

The inside of the housing may be filled with an insulating resin.

The semiconductor package may further include a molding surrounding the second substrate and the second semiconductor device so as to isolate them from the outside.

### BRIEF DESCRIPTION OF THE DRAWINGS

FIG. 1 is an exemplified diagram showing a semiconductor package according to a preferred embodiment of the present invention.

FIG. 2 is an exemplified diagram showing a semiconductor package according to another preferred embodiment of the present invention.

FIG. 3 is an exemplified diagram showing a clip according to the preferred embodiment of the present invention.

FIG. 4 is an exemplified diagram showing a clip according to another preferred embodiment of the present invention.

FIG. 5 is an exemplified diagram showing a clip according to another preferred embodiment of the present invention.

### DESCRIPTION OF THE PREFERRED EMBODIMENTS

Various features and advantages of the present invention will be more obvious from the following description with reference to the accompanying drawings.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe most appropriately the best method he or she knows for carrying out the invention.

The above and other objects, features and advantages of the present invention will be more clearly understood from preferred embodiments and the following detailed description taken in conjunction with the accompanying drawings. In the specification, in adding reference numerals to components throughout the drawings, it is to be noted that like reference numerals designate like components even though components are shown in different drawings.

Further, when it is determined that the detailed description of the known art related to the present invention may obscure the gist of the present invention, the detailed description thereof will be omitted. In the description, the terms “first”, “second”, and so on are used to distinguish one element from another element, and the elements are not defined by the above terms.

Hereinafter, a semiconductor package according to preferred embodiments of the present invention will be described in detail with reference to the accompanying drawings.

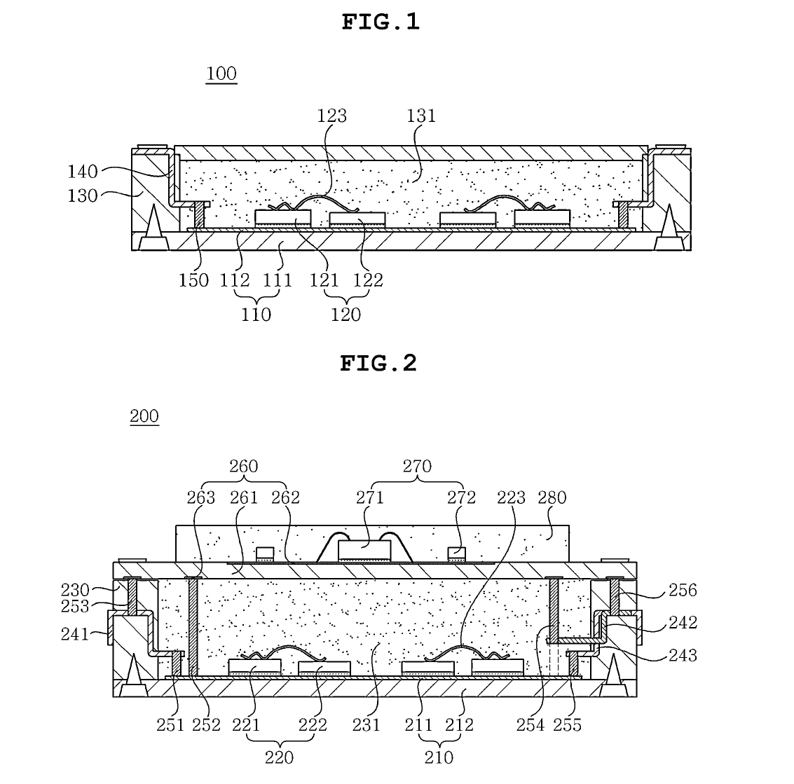

FIG. 1 is an exemplified diagram showing a semiconductor package according to a preferred embodiment of the present invention.

Referring to FIG. 1, a semiconductor package 100 may include a substrate 110, a semiconductor device 120, a housing 130, a lead frame 140, and a clip 150.

The substrate 110 may include an insulating substrate 111 and a conductive track 112 formed on the insulating substrate 111. The conductive track 112 may be made of conductive metals. The conductive track 112 may be electrically connected with the semiconductor device 120 formed on the substrate 110.

The semiconductor device 120 may include power devices 121 and control devices 122. The semiconductor device 120 may be electrically connected with each other by wires 123. In addition, the semiconductor device 120 may be mounted on the conductive track 112. Further, the semiconductor device 120 may be bonded with the conductive track 112 by an adhesive. As the adhesive, conductive adhesives, such as solder, conductive epoxy, or the like, may be used.

The housing 130 is configured to surround the semiconductor device 120 and the substrate 110 so as to isolate them from the outside. The housing 130 may be made of polymer materials such as plastic, or the like. The inside of the housing 130 may be filled with an insulating resin 131 so as to protect internal components such as the semiconductor device 120, the substrate 110, or the like. For example, the insulating resin 131 may be silicon.

The lead frame 140 may be electrically connected with the substrate 110 to provide electrical signals of the semiconductor device 120. The lead frame 140 may be formed to be protruded to the outside of the housing 130. The position of the lead frame 140 protruded to the outside of the housing 130 may be changed according to a design. The lead frame 140 may be connected with the clip 150 according to the embodiment of the present invention to electrically connect with the substrate 110.

The clip 150 is configured to electrically connect the substrate 110 with the lead frame 140. The clip 150 may be made of conductive metals. In addition, the clip 150 may be made of elastic materials having elastic force. In addition, the clip 150 may be thinly formed so as to be easily machined within a range in which the clip is not permanently deformed. The clip 150 may be connected with the substrate 110 and the lead frame 140 so as to electrically connect the substrate 110 and the lead frame 140 with each other. That is, the clip 150 may be connected with the substrate 110 and the lead frame 140 by an assembling manner rather than by a bonding manner.

Although not shown in the drawing, the semiconductor package 100 according to the preferred embodiment of the present invention may include a radiating plate (not shown) on at least one of the top portion or the bottom portion of the housing 130.

The preferred embodiment of the present invention can stably transfer the electrical signals by using the clip 150 made of the conductive metals rather than using the wire bonding, so as to electrically connect between the lead frame 140 and the substrate 110. In addition, the clip 150 according to the preferred embodiment of the present invention has the contact structure and thus, is stronger against the thermal and physical impact than the bonding such as the wire bonding, or the like, thereby achieving the long-term reliability. In addition, the clip 150 according to the preferred embodiments of the present invention can be implemented by the simple assembling process, thereby improving the productivity and yield of the semiconductor package.

FIG. 2 is an exemplified diagram showing a semiconductor package according to another preferred embodiment of the present invention.

Referring to FIG. 2, a semiconductor package 200 may include a first substrate 210, a second substrate 260, a first semiconductor device 220, a second semiconductor device 270, a housing 230, a first lead frame 241, a second lead frame 242, a first clip 251, a second clip 252, and a third clip 253.

The first substrate 210 may include the first insulating substrate 211 and the first conductive track 212 formed on the first insulating substrate 211. The first conductive track 212 may be made of conductive metals. The first conductive track 212 may be electrically connected with the first semiconductor device 220 formed on the substrate 210.

The first semiconductor device 220 may include power devices 221 and control devices 222. The first semiconductors 220 may be electrically connected with each other by wires 223. In addition, the first semiconductor device 220 may be mounted on the first conductive track 212. The first semiconductor device 220 may be bonded to the first conductive track 212 by an adhesive. As the adhesive, conductive adhesives, such as solder, conductive epoxy, or the like, may be used.

The second substrate 260 may be formed on the first substrate 210 at a predetermined distance.

The second substrate 260 may include a second insulating substrate 261, a second conductive track 262 formed on the second insulating substrate 261, and a connection pad 263 formed on the bottom portion of the second insulating substrate 261. The second conductive track 262 and the connection pad 263 may be made of conductive metals. The second conductive track 262 may be electrically connected with the second semiconductor device 270 mounted on the second substrate 260. In addition, the connection pad 263 formed on the bottom portion of the second insulating substrate 261 may be electrically connected with the first substrate 210, the first lead frame 241, or the second lead frame 242.

The second semiconductor device 270 may include at least one of a passive device 271 and active devices 272. The second semiconductor device 270 is mounted in the second conductive track 262 and may be electrically connected with the second conductive track 262. The second semiconductor device 270 may be bonded to the second conductive track 262 by an adhesive. As the adhesive, conductive adhesives, such as solder, conductive epoxy, or the like, may be used. In order to protect the second semiconductor device 270 as described above, a molding 280 surrounding the second semiconductor device 270 may be formed on the second substrate 260.

The housing 230 is configured to surround the first semiconductor device 220 and the first substrate 210 so as to isolate them from the outside. The housing 230 may be made of polymer materials such as plastic, or the like. The inside of the housing 230 may be filled with an insulating resin 231 so as to protect internal components such as the first semiconductor device 220, the first substrate 210, or the like. For example, the insulating resin 231 may be silicon.

The first lead frame 241 to the third lead frame 243 are electrically connected with the first substrate 210 or the second substrate 260 to provide the electrical signals of the first semiconductor device 220 or the second semiconductor device 270. At least one of the first lead frame 241 to the third lead frame 243 may be formed to be protruded to the outside of the housing 230. Among the first lead frame 241 to the third lead frame 243, the position of the lead frame protruded to the outside of the housing 230 may be changed according to the design. The first lead frame 241 to the third lead frame 243 may connect with a first clip 251 to a sixth clip 256 according to the preferred embodiment of the present invention so as to electrically connect with the first substrate 210 or the second substrate 260. Although the preferred embodiment of the present invention describes an example of the first lead frame 241, the second lead frame 242, and the third lead frame 243, those skilled in the art can easily change the number, shape, position, or the like, of lead frames according to the design.

The first clip 251 to the sixth clip 256 may be electrically connected with the first substrate 210, the second substrate 260, the first lead frame 241, or the third lead frame 243. The first clip 251 to the sixth clip 256 may be made of conductive metals. The first clip 251 to the sixth clip 256 may be made of elastic materials having elastic force. In addition, the first clip 251 to the sixth clip 256 may be thinly formed so as to be easily machined within a range in which the first clip 251 to the sixth clip 256 are not permanently deformed.

For example, as shown in FIG. 2, one end of the first clip 251 contacts one end of the first lead frame 241 and the other end thereof may contact the first substrate 210.

One end of the second clip 252 may contact the first substrate 210 and the other end thereof may contact the second substrate 260.

One end of the third clip 253 may contact the second substrate 260 and the other end thereof may contact the first lead frame 241.

One end of the fourth clip 254 may contact the second lead frame 242 and the other end thereof may contact the second substrate 260.

One end of the fifth clip 255 may contact the first substrate 210 and the other end thereof may contact the third lead frame 243.

One end of the sixth clip 256 may contact the second substrate 260 and the other end thereof may contact the second lead frame.

The first clip 251 to the sixth clip 256 may be electrically connected with the first substrate 210, the second substrate 260, the first lead frame 241, and the second lead frame 242 in a contact manner. That is, the first clip 251 to the sixth clip 256 may be electrically connected with the first substrate 210, the second substrate 260, the first lead frame 241, and the second lead frame 242 in an assembling manner rather than in a bonding manner.

The preferred embodiments of the present invention describe the first clip 251 to the sixth clip 256 by way of example but are not limited thereto. That is, the number, shape, connection relation, or the like, of clips may be easily changed by the design of those skilled in the art.

In addition, although not shown in the drawing, the semiconductor package 200 according to the preferred embodiment of the present invention may include a radiating plate (not shown) on the bottom portion of the housing 230.

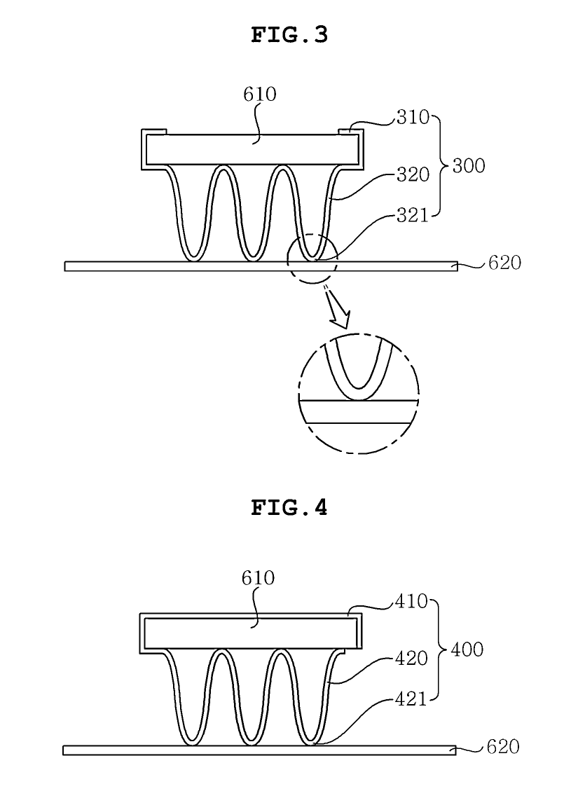

FIG. 3 is an exemplified diagram showing a clip according to the preferred embodiment of the present invention.

Referring to FIG. 3, the clip 300 may include a fastening part 310 and a contact part 320.

The fastening part 310 is formed on the top portion of the clip 300. The fastening part 310 is inserted with the end of the lead frame 610. Since the clip 300 is made of conductive metals having elastic force, it is easy to insert the end of the lead frame 610 by the elastic force. The fastening part 310 fastens the lead frame 610 in a shape surrounding a side of the end of the lead frame 610 and may be electrically connected with the lead frame 610.

The contact part 320 is formed on the bottom portion of the clip 300. The contact part 320 may contact the top surface of the conductive track 620. The contact part 320 may contact the conductive track 620 and thus, may be electrically connected with the conductive track 620. The contact part 320 may include a plurality of contact ends 321. The contact part 320 may be formed in a plurality of curved shapes and thus, the plurality of contact ends 321 contacting the conductive track 620 may be formed. The contact end 321 may be formed in a curved shape so as to expand an area contacting the conductive track 620. As described above, the electric conductivity may be further improved than the case in which the contact end 321 is only one by forming the plurality of contact ends 321. In addition, the contact part 320 may contact the conductive track 620 and the bottom surface of the lead frame 610. The contact part 320 contacts the top surface of the conductive track 620 and the bottom surface of the lead frame 610 in a zigzag form, thereby improving the electric conductivity between the conductive track 620 and the lead frame 610.

The preferred embodiment of the present invention describes an example that the contact part 320 contacts the conductive track 620, but is not limited thereto. The contact part 320 may be connected with a pattern such as a connection pad, or the like, that may be electrically connected with the substrate.

FIG. 4 is an exemplified diagram showing a clip according to another preferred embodiment of the present invention.

Referring to FIG. 4, the clip 400 may include a fastening part 410 and a contact part 420.

The fastening part 410 is formed on the top portion of the clip 400. The fastening part 410 is inserted with the end of the lead frame 610. Since the clip 400 is made of conductive metals having elastic force, it is easy to insert the end of the lead frame 610 by the elastic force. The fastening part 410 fastens the lead frame 610 in a form surrounding the side and the top surface of the end of the lead frame 610 and thus, may be electrically connected with the lead frame 610.

The contact part 420 is formed on the bottom portion of the clip 400. The contact part 420 may contact the top surface of the conductive track 620. The contact part 420 may contact the conductive track 620 and thus, may be electrically connected with the conductive track 620. The contact part 420 may include a plurality of contact ends 421. The contact part 420 may be formed in a plurality of curved forms and thus, the plurality of contact ends 421 contacting the conductive track 620 may be formed. The contact end 421 may be formed in a curved shape so as to expand an area contacting the conductive track 620. As described above, the electric conductivity may be more improved than the case in which the contact end 421 is only one, by forming the plurality of contact ends 421. In addition, the contact part 420 may contact the conductive track 620 and the bottom surface of the lead frame 610. The contact part 420 contacts the top surface of the conductive track 620 and the bottom surface of the lead frame 610 in a zigzag form, thereby improving the electric conductivity between the conductive track 620 and the lead frame 610.

The preferred embodiment of the present invention describes an example that the contact part 420 contacts the conductive track 620, but is not limited thereto. The contact part 420 may be connected with a pattern such as a connection pad, or the like, that may be electrically connected with the substrate.

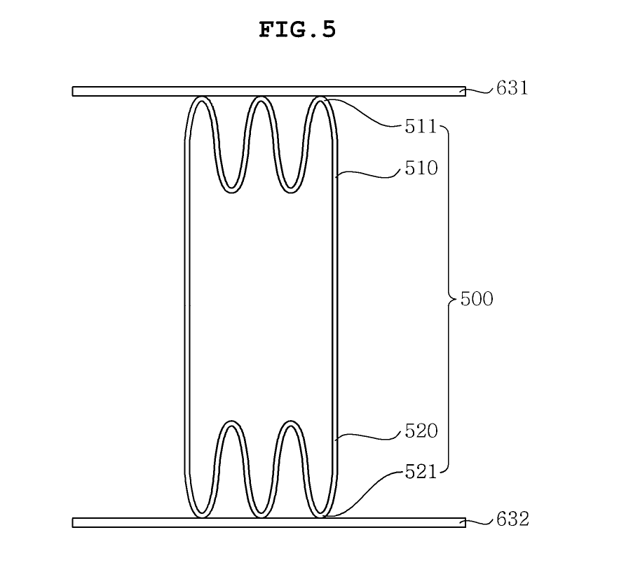

FIG. 5 is an exemplified diagram showing a clip according to another preferred embodiment of the present invention.

Referring to FIG. 5, a clip 500 may include a first contact part 510 and a second contact part 520.

The first contact part 510 is formed on the top portion of the clip 500. The first contact part 510 may contact the first conductive track 631 formed on the substrate that is positioned on the top portion of the clip 500. The first contact part 510 contacts the first conductive track 631 and thus, may be electrically connected with the substrate disposed on the top portion of the clip 500. The first contact part 510 may include a plurality of first contact ends 511. The first contact part 510 is formed in a plurality of curved shapes and may form a plurality of first contact ends 511 contacting the first conductive track 631. The first contact end 511 may be formed in a curved shape so as to expand an area contacting the first conductive track 631. As described above, the electric conductivity may be more improved than the case in which the first contact end 511 is only one, by forming the plurality of the first contact ends 511.

The second contact part 520 is formed on the bottom portion of the clip 500. The second contact part 520 may contact the second conductive track 632 formed on the substrate that is positioned on the bottom portion of the clip 500. The second contact part 520 contacts the second conductive track 632 and thus, may be electrically connected with the substrate disposed on the bottom portion of the clip 500. The second contact part 520 may include a plurality of second contact ends 521. The second contact part 520 is formed in a plurality of curved shapes and may form a plurality of second contact ends 511 contacting the second conductive track 632. The second contact end 521 may be formed in a curved shape so as to expand an area contacting the second conductive track 632. As described above, the electric conductivity may be more improved than the case in which the second contact end 521 is only one, by forming the plurality of second contact ends 521.

The preferred embodiments of the present invention show that the first contact part 510 and the second contact part 520 contact the first conductive track 631 and the second conductive track 632 but are not limited thereto. The first contact part 510 and the second contact part 520 may be connected with the pattern such as the connection pad, or the like, that may be electrically connected with the substrate disposed on the top and bottom portions of the clip 500.

The semiconductor package according to the preferred embodiments of the present invention can easily implement the stable transfer of electrical signals by using the clip using the member for electrical connection. The semiconductor package according to the preferred embodiments of the present invention has the contact structure of the clips and is stronger against the thermal and physical impact than the wire bonding or the soldering, thereby improving the long-term reliability. Further, the semiconductor package according to the preferred embodiments of the present invention can be implemented by the simple assembling process, thereby improving the productivity and yield of the semiconductor package.

The semiconductor package according to the preferred embodiments of the present invention can easily implement the stable transfer of electrical signals by using the clip using the member for electrical connection.

The semiconductor package according to the preferred embodiments of the present invention has the contact structure of the clips and is stronger against the thermal and physical impact than the wire bonding or the soldering, thereby improving the long-term reliability.

The semiconductor package according to the preferred embodiments of the present invention can be implemented by the simple assembling process, thereby improving the productivity and yield of the semiconductor package.

Although the embodiment of the present invention has been disclosed for illustrative purposes, it will be appreciated that a semiconductor package according to the invention is not limited thereby, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A semiconductor package, comprising:
a substrate having a semiconductor device mounted on a top portion thereof;
a housing surrounding the semiconductor device and the substrate so as to isolate them from the outside;
at least one lead frame disposed on the top portion of the substrate while being spaced apart from one another; and
a clip electrically connecting the substrate with at least one lead frame.

2. The semiconductor package as set forth in claim 1, wherein the clip is made of conductive metals.

3. The semiconductor package as set forth in claim 1, wherein the clip is an elastic member.

4. The semiconductor package as set forth in claim 1, wherein a top portion of the clip is fastened with the lead frame by being inserted in a form surrounding both sides of an end of the lead frame.

5. The semiconductor package as set forth in claim 1, wherein the top portion of the clip is fastened with the lead frame by being inserted in a form surrounding both sides and the top portion of the end of the lead frame.

6. The semiconductor package as set forth in claim 1, wherein a bottom portion of the clip has at least one end contacting the substrate.

7. The semiconductor package as set forth in claim 1, wherein an inside of the housing is filled with an insulating resin.

8. A semiconductor package, comprising:
a first substrate having a semiconductor device mounted on a top portion thereof;
a second substrate formed so as to be spaced apart from the first substrate and having a second semiconductor device mounted thereon;
a housing surrounding the first semiconductor device and the first substrate so as to isolate them from the outside;
at least one lead frame disposed on a top portion of the substrate while being spaced apart from one another;
a first clip electrically connecting the first substrate with at least one lead frame; and
a second clip electrically connecting the first substrate with the second substrate.

9. The semiconductor package as set forth in claim 8, further comprising a third clip electrically connecting the second substrate with the at least one lead frame.

10. The semiconductor package as set forth in claim 9, wherein the first clip to the third clip are made of conductive metals.

11. The semiconductor package as set forth in claim 9, wherein the first clip to the third clip are an elastic member.

12. The semiconductor package as set forth in claim 9, wherein the top portions of at least one of the first clip to the third clip are fastened with each other by being inserted in a form surrounding both sides of the end of the at least one lead frame.

13. The semiconductor package as set forth in claim 9, wherein the top portions of at least one of the first clip to the third clip are fastened with each other by being inserted in a form surrounding both sides and the top portion of the end of the at least one lead frame.

14. The semiconductor package as set forth in claim 9, wherein the bottom portions of at least one of the first clip to the third clip have at least one contact end contacting the first substrate or the second substrate.

15. The semiconductor package as set forth in claim 9, wherein the top portion of the second clip has a contact end contacting the first substrate or the second substrate.

16. The semiconductor package as set forth in claim 9, wherein the inside of the housing is filled with an insulating resin.

17. The semiconductor package as set forth in claim 8, further comprising a molding surrounding the second substrate and the second semiconductor device so as to isolate them from the outside.
